(19) United States
(12) Patent Application Publication
(10) Pub. No.: US 2013/0146129 A1
(43) Pub. Date: Jun. 13, 2013

(54) CROSS-LINKABLE EDGE SEALANT FOR PHOTOVOLTAIC MODULES

(71) Applicant: E. I. DU PONT DE NEMOURS AND COMPANY, Wilmington, DE (US)

(72) Inventors: David D. Zhang, Wilmington, DE (US); George Wyatt Prejean, Orange, TX (US); Jiawei Zhang, Shanghai (CN); Minji Zhao, Shanghai (CN); Kevin J. Leary, Middletown, DE (US)

(73) Assignee: E. I. DU PONT DE NEMOURS AND COMPANY, Wilmington, DE (US)

(21) Appl. No.: 13/709,687

(22) Filed: Dec. 10, 2012

(30) Foreign Application Priority Data
Dec. 9, 2011 (CN) 201110408220.4

(51) Int. Cl. H01L 31/048; H01L 31/18

(52) U.S. Cl. CPC H01L 31/0481; H01L 31/18
USPC 136/251; 438/66

(57) ABSTRACT

A framed solar cell module comprises: (a) a platelike solar cell module that comprises a solar cell element formed of one or a plurality of electrically interconnected solar cells; (b) a frame body that has a groove portion into which the outer periphery of the solar cell module is fitted; and (c) a sealant material that is so provided as to fill up a space between the outer periphery of the solar cell module and the groove portion of the frame body, and wherein the sealant material is formed of a cross-linkable blend composition of two ethylene copolymers.

### CROSS-REFERENCE TO RELATED APPLICATION

This application claims priority under 35 U.S.C. §119(a) to Patent Application for Invention No. 201110408220.4, filed in the State Intellectual Property Office of the People's Republic of China on Dec. 9, 2011, which is incorporated herein by reference in its entirety.

### FIELD OF THE INVENTION

The disclosure is related to framed solar cell modules using a novel edge seal material.

### BACKGROUND OF THE INVENTION

Several patents and publications are cited in this description in order to more fully describe the state of the art to which this invention pertains. The entire disclosure of each of these patents and publications is incorporated by reference herein.

Currently, silicone glues are often used as the edge seal material to bond the aluminum frames around solar cell modules. Using silicone glue as the edge seal material has a number of drawbacks. First, after silicone glue is applied, excess residues are often left on the module surfaces and need to be wiped away. This not only causes higher manufacturing cost, but also causes environment issues. Secondly, prolonged (at least about 6 hours) curing time is required for silicone glue and therefore the production efficiency is reduced. Moreover, butanone oxime is often released when silicone glue is used and therefore causes odor issue. Finally, the excessive waste that is generated when silicone glue is used also causes higher manufacturing cost. Thus, there is still a need to develop a new edge seal material that is environmentally friendly, cost effective, easy to handle, and that requires shorter curing time.

### SUMMARY OF THE INVENTION

Provided herein is a framed solar cell module comprising:
(a) a platelike solar cell module comprising a solar cell element formed of one or a plurality of electrically interconnected solar cells;
(b) a frame body having a groove portion, into which the outer periphery of the solar cell module is fitted; and
(c) a sealant material so provided as to fill up a space between the outer periphery of the solar cell module and the groove portion of the frame body, the sealant material being formed of a cross-linkable blend composition containing 10-90 wt % of an Ethylene Copolymer-1 and 10-90 wt % of an Ethylene Copolymer-2,

with the total wt % of all the components comprised in the cross-linkable blend composition totaling to 100 wt %, and wherein,
(i) the Ethylene Copolymer-1 consists essentially of copolymerized units of ethylene, optionally up to 40 wt % of copolymerized units of a first olefin having a formula of CH₂═C(R¹)CO₂R², and 2-30 wt % of copolymerized units of a second olefin having a formula of CH₂═C(R³)COOH, with the total wt % of all the copolymerized units comprised in the Ethylene Copolymer-1 totaling to 100 wt %, and with R¹ being hydrogen or an alkyl group, R² being an alkyl group, and R³ being hydrogen or an alkyl group;
(ii) the Ethylene Copolymer-2 consists essentially of copolymerized units of ethylene, optionally up to 40 wt % of copolymerized units of the first olefin, and 3-15 wt % of copolymerized units of a third olefin having a formula of CH₂═C(R⁴)-D, with the total wt % of all the copolymerized units comprised in the Ethylene Copolymer-2 totaling to 100 wt %, and with R⁴ being hydrogen or an alkyl group and -D being a moiety selected from the group consisting of —CO₂R⁵, —CO₂R⁶—R⁵, —R⁶—R⁵, —O—R⁵, and —R⁵, and with R⁵ being a moiety containing an epoxy group and R⁶ being an alkylene group; and
(iii) none of the first, second or third olefin is a dicarboxylic acid or a di-ester, mono-ester or anhydride of the dicarboxylic acid.

In one embodiment of the framed solar cell module, the sealant material is formed of a product of cross-linking the cross-linkable blend composition described above. In this cross-linked product, at least a portion of the carboxylic acid groups comprised in the Ethylene Copolymer-1 are reacted with at least a portion of the epoxy groups comprised in the Ethylene Copolymer-2 to form cross-links between the Ethylene Copolymer-1 and the Ethylene Copolymer-2.

In a further embodiment of the framed solar cell module, the weight ratio of the Ethylene Copolymer-1 and the Ethylene Copolymer-2 comprised in the cross-linkable blend composition ranges from 80:20 to 20:80, or from 70:30 to 30:70; or from 60:40 to 40:60.

In a yet further embodiment of the framed solar cell module, the first olefin is selected from the group consisting of methyl acrylate, methyl methacrylate, ethyl acrylate, ethyl methacrylate, butyl acrylate, and butyl methacrylate, or the first olefin is selected from the group consisting of n-butyl acrylate, iso-butyl acrylate, methyl methacrylate, and n-butyl methacrylate.

In a yet further embodiment of the framed solar cell module, the second olefin is an acrylic acid or a methacrylic acid.

In a yet further embodiment of the framed solar cell module, the moiety R⁵ is a glycidyl group, a 1,2-cyclohexenyl oxide group, or a 1,2-epoxy group.

In a yet further embodiment of the framed solar cell module, the Ethylene Copolymer-1 comprises 5-40 wt %, or 10-35 wt %, or 10-30 wt % of copolymerized units of the first olefin, with the total wt % of all the copolymerized units comprised in the Ethylene Copolymer-1 totaling to 100 wt %.

In a yet further embodiment of the framed solar cell module, the Ethylene Copolymer-1 comprises 5-20 wt % or 5-15 wt % of copolymerized units of the second olefin, with the total wt % of all the copolymerized units comprised in the Ethylene Copolymer-1 totaling to 100 wt %.

In a yet further embodiment of the framed solar cell module, the Ethylene Copolymer-1 has a melt flow rate of 5 g/10 min or higher, or 30 g/10 min or higher, or 30-500 g/10 min, as determined in accordance with ASTM D1238 at 190° C. and under a weight of 2.16 kg.

In a yet further embodiment of the framed solar cell module, the Ethylene Copolymer-1 is a copolymer of ethylene/n-butyl acrylate/acrylic acid.

In a yet further embodiment of the framed solar cell module, the Ethylene Copolymer-2 comprises 3-10 wt % or 4-7 wt % of copolymerized units of the third olefin, with the total wt % of all the copolymerized units comprised in the Ethylene Copolymer-2 totaling to 100 wt %.

In a yet further embodiment of the framed solar cell module, the Ethylene Copolymer-2 comprises 5-40 wt %, or 10-40 wt %, or 20-40 wt %, or 20-35 wt % of copolymerized units of the first olefin, with the total wt % of all the copolymerized units comprised in the Ethylene Copolymer-2 totaling to 100 wt %.

In a yet further embodiment of the framed solar cell module, the Ethylene Copolymer-2 has a melt flow rate of 5-300 g/10 min or 5-100 g/10 min, as determined in accordance with ASTM D1238 at 190° C. and under a weight of 2.16 kg.

In a yet further embodiment of the framed solar cell module, the Ethylene Copolymer-2 is a copolymer of ethylene/n-butyl acrylate/glycidyl methacrylate.

In a yet further embodiment of the framed solar cell module, the frame body is formed of a metallic material or a plastic material.

Further provided herein is a method for preparing a framed solar cell module, comprising the steps of:
(a) providing a platelike solar cell module comprising a solar cell element formed of one or a plurality of electrically interconnected solar cells;
(b) providing a frame body having a groove portion;
(c) providing a sealant material formed of the cross-linkable blend composition described above; and
(d) attaching the outer periphery of the solar cell module into the inside of the groove portion of the frame body, with the sealant material filling up the space between the outer periphery of the solar cell module and the frame body, to obtain the framed solar cell module.

In one embodiment of the method for preparing the framed solar cell module, step (d) comprises: (i) attaching a polymer strip formed of the sealant material around the outer periphery of the solar cell module; and (ii) attaching the outer periphery of the solar cell module, which is covered by the polymer strip, into the inside of the groove portion of the frame body.

In a further embodiment of the method for preparing the framed solar cell module, step (d) comprises: (i) attaching a polymer strip formed of the sealant material over the inside of the groove portion of the frame body; and (ii) attaching the outer periphery of the solar cell module into the inside of the groove portion of the frame body, which is covered by the polymer strip.

In a yet further embodiment of the method for preparing the framed solar cell module, step (d) comprises: (i) extrusion coating the sealant material around the outer periphery of the solar cell module; and (ii) attaching the outer periphery of the solar cell module, which is extrusion coated with the sealant material, into the inside of the groove portion of the frame body.

In a yet further embodiment of the method for preparing the framed solar cell module, step (d) comprises: (i) extrusion coating the sealant material over the inside of the groove portion of the frame body; and (ii) attaching the outer periphery of the solar cell module into the inside of the groove portion of the frame body, which is extrusion coated with the sealant material.

In a yet further embodiment of the method for preparing the framed solar cell module, the method further comprises step (e) subjecting the framed solar cell module obtained in step (d) to curing at a temperature of 135° C. or higher, or to 140° C.-180° C. In step (e), the curing duration may be 5-60 minutes, or 5-30 minutes, or 5-20 minutes.

Yet further provided herein is a method for preparing a plastic framed solar cell module, comprising the steps of:
(a) providing a platelike solar cell module comprising a solar cell element formed of one or a plurality of electrically interconnected solar cells;
(b) co-extruding a polymer composition and the cross-linkable blend composition described to form a frame body, wherein the frame body has a groove portion and the inside layer of the groove portion is formed of the cross-linkable blend composition; and
(c) attaching the outer periphery of the solar cell module into the inside of the groove portion of the frame body.

In one embodiment of the method form preparing the plastic framed solar cell module, the method further comprises step (d) subjecting the framed solar cell module obtained in step (c) to curing at a temperature of 135° C. or higher, or to 140° C.-180° C. In step (d), the curing duration may be 5-60 minutes, or 5-30 minutes, or 5-20 minutes.

These and various other advantages and features of novelty that characterize the invention are pointed out with particularity in the claims annexed hereto and forming a part hereof. For a better understanding of the invention, its advantages, and the objects obtained by its use, however, reference should be made to the drawings which form a further part hereof, and to the accompanying descriptive matter, in which there is illustrated and described a preferred embodiment of the invention.

### BRIEF DESCRIPTION OF THE DRAWINGS

FIG. 1 is a not-to-scale cross-sectional view of one embodiment of the framed solar cell module disclosed herein.

FIG. 2 depicts one embodiment of the process for preparing the framed solar cell module disclosed herein.

FIG. 3 depicts a further embodiment of the process for preparing the framed solar cell module disclosed herein.

FIG. 4 depicts a yet further embodiment of the process for preparing the framed solar cell module disclosed herein.

FIG. 5 depicts a yet further embodiment of the process for preparing the framed solar cell module disclosed herein.

FIG. 6 depicts a yet further embodiment of the process for preparing the framed solar cell module disclosed herein.

### DETAILED DESCRIPTION OF THE INVENTION

The following definitions apply to the terms as used throughout this specification, unless otherwise limited in specific instances.

Unless otherwise defined, all technical and scientific terms used herein have the same meaning as commonly understood by one of ordinary skill in the art to which this invention belongs. In case of conflict, the specification, including definitions, will control.

When a composition, a process, a structure, or a portion of a composition, a process, or a structure, is described herein using an open-ended term such as “comprising,” unless otherwise stated the description also includes an embodiment that “consists essentially of” or “consists of” the elements of the composition, the process, the structure, or the portion of the composition, the process, or the structure.

The term “or”, as used herein, is inclusive; that is, the phrase “A or B” means “A, B, or both A and B”. More specifically, a condition “A or B” is satisfied by any one of the following: A is true (or present) and B is false (or not present); A is false (or not present) and B is true (or present); or both A and B are true (or present). Exclusive “or” is designated herein by terms such as “either A or B” and “one of A or B”, for example.

In addition, the ranges set forth herein include their endpoints unless expressly stated otherwise. Further, when an amount, concentration, or other value or parameter is given as a range, one or more preferred ranges or a list of upper preferable values and lower preferable values, this is to be understood as specifically disclosing all ranges formed from any pair of any upper range limit or preferred value and any lower range limit or preferred value, regardless of whether such pairs are separately disclosed. The scope of the invention is not limited to the specific values recited when defining a range.

As used herein, the term “copolymer” refers to polymers comprising copolymerized units resulting from copolymerization of two or more comonomers. In this connection, a copolymer may be described herein with reference to its constituent comonomers or to the amounts of its constituent comonomers, for example “a copolymer comprising ethylene and 18 weight % of acrylic acid”, or a similar description. Such a description may be considered informal in that it does not refer to the comonomers as copolymerized units; in that it does not include a conventional nomenclature for the copolymer, for example International Union of Pure and Applied Chemistry (IUPAC) nomenclature; in that it does not use product-by-process terminology; or for another reason. As used herein, however, a description of a copolymer with reference to its constituent comonomers or to the amounts of its constituent comonomers means that the copolymer contains copolymerized units (in the specified amounts when specified) of the specified comonomers. It follows as a corollary that a copolymer is not the product of a reaction mixture containing given comonomers in given amounts, unless expressly stated in limited circumstances to be such.

The terms “epoxy group”, “ethylene oxide group” and “oxirane ring” are synonymous and used interchangeably herein to refer to a substituted or unsubstituted group having the formula —CROCR², wherein the oxygen atom is bound to both carbons and the carbons are bound to each other. When the R groups are hydrogen atoms, the ethylene oxide group is unsubstituted. The ethylene oxide group may be singly or multiply substituted. Stated alternatively, one, two or three of the R groups may be other than hydrogen atoms.

The terms “alkyl group” and “alkylene group”, as used herein alone or in combined form, such as, for example, “alkoxy group”, refer to saturated hydrocarbon groups that have from 1 to 8 carbon atoms and that may be branched or unbranched. An alkyl group has one bond to a carbon atom available for substitution, and an alkylene group has two bonds to one or more carbon atoms available for substitution.

Finally, the term “solar cell” as used herein includes any article which can convert light into electrical energy. Solar cells useful in the invention include, but are not limited to, wafer-based solar cells (e.g., c-Si or mc-Si based solar cells), thin film solar cells (e.g., a-Si, μc-Si, CdTe, or CI(G)S based solar cells), and organic solar cells.

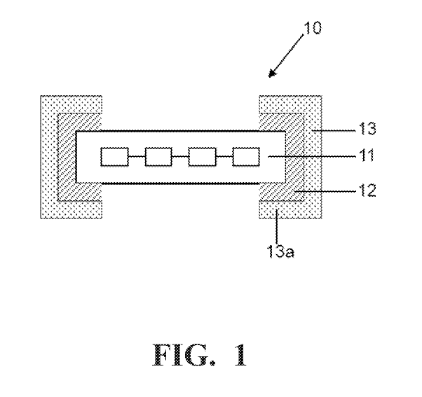

Referring now to the drawings, wherein like reference letters and numerals designate corresponding structure throughout the views, and referring in particular to FIG. 1, provided herein is a framed solar cell module (10) comprising: (a) a platelike solar cell module (11) that comprises a solar cell element formed of one or a plurality of electrically interconnected solar cells; (b) a frame body (13) that has a groove portion (13a) into which the outer periphery of the solar cell module (11) is fitted; and (c) a sealant material (or edge seal material) (12) that is so provided as to fill up a space between the outer periphery of the solar cell module (11) and the groove portion (13a) of the frame body (13), and wherein the sealant material (12) is formed of a cross-linkable blend composition such as that disclosed in U.S. Patent Publication No. US2011/0023943. Within the framed solar cell module (10), the solar cell module (11) and frame body (13) are bonded by the sealant material (12) that is positioned therebetween. In addition, the sealant material (12) also serves as a moisture barrier for the framed module (10).

More specifically, the cross-linkable blend composition used herein comprises about 10-90 wt % of an Ethylene Copolymer-1 (ECP-1) and about 10-90 wt % of an Ethylene Copolymer-2 (ECP-2), with the total wt % of all the components comprised in the blend composition totaling to 100 wt %. The ECP-1 used herein consists essentially of copolymerized units of ethylene, optionally up to about 40 wt % of copolymerized units of a first olefin having a formula of CH₂═C(R¹)CO₂R², and about 2-30 wt % of copolymerized units of a second olefin having a formula of CH₂═C(R³)COOH, with the total wt % of all the copolymerized units comprised in the ECP-1 totaling to 100 wt %, and wherein R¹ represents hydrogen or an alkyl group; R² represents an alkyl group; and R³ represents hydrogen or an alkyl group. The ECP-2 used herein consists essentially of copolymerized units of ethylene, optionally up to about 40 wt % of copolymerized units of the first olefin, and about 3-15 wt % of copolymerized units of a third olefin having a formula of CH₂═C(R⁴)-D, with the total wt % of all the copolymerized units comprised in the ECP-2 totaling to 100 wt %, and wherein R⁴ represents hydrogen or an alkyl group and -D represents a moiety selected from the group consisting of —CO₂R⁵, —CO₂R⁶—R⁵, —R⁶—R⁵, —O—R⁵, and —R⁵, with R⁵ being a moiety containing an epoxy group and R⁶ being an alkylene group.

In addition, it is understood that none of the first, second, or third olefins used herein is a dicarboxylic acid or a di-ester, mono-ester or anhydride of the dicarboxylic acid.

Suitable first olefins having the formula CH₂═C(R¹)CO₂R² include, without limitation, methyl acrylate, methyl methacrylate, ethyl acrylate, ethyl methacrylate, butyl acrylate, and butyl methacrylate. Preferably, the first olefin is selected from n-butyl acrylate, iso-butyl acrylate, methyl methacrylate, and n-butyl methacrylate. Suitable second olefins having the formula CH₂═C(R³)COOH include, without limitation, acrylic acids and methacrylic acids. In addition, in the third olefin of formula CH₂═C(R⁴)-D, the moiety R⁵ that is comprised in D is a moiety containing an epoxy group, such as a glycidyl group, a 1,2-cyclohexenyl oxide group, or a 1,2-epoxy group.

In accordance with the present disclosure, the ECP-1 is not an ionomer. In particular, the carboxylic acid groups of ECP-1 are present in protonated form and no significant amount of these carboxylic acid groups is neutralized to form carboxylate salts.

In addition, the ECP-1 may optionally further comprise other suitable additional comonomers, such as unsaturated carboxylic acids having 2 to 10, or preferably 3 to 8 carbons, or derivatives thereof. Suitable acid derivatives include acid anhydrides, amides, and esters. However, the ECP-1 preferably does not incorporate the other additional comonomers in any significant amount. In one embodiment, the ECP-1 comprises about 5-40 wt %, or about 10-35 wt %, or about 10-30 wt % of copolymerized units of the first olefin of formula CH₂═C(R¹)CO₂R², when the first olefin is present. The ECP-1 further comprises about 2-30 wt %, or about 5-20 wt %, or about 5-15 wt % of copolymerized units of the second olefin of the formula CH₂═C(R³)COOH. The remainder of the ECP-1 comprises copolymerized units of ethylene and up to about 5 wt % of optional additional comonomers. These weight percentages are based on the total weight of the ECP-1. Moreover, the ECP-1 may have a melt flow rate (MFR) of about 5 g/10 min or higher, or about 30 g/10 min or higher, or about 30-500 g/10 min, as determined in accordance with ASTM D1238 at 190° C. and under a weight of 2.16 kg.

Polymers suitable for use as ECP-1 also may be obtained commercially. For example, the ECP-1 used herein may be a copolymer of ethylene/n-butyl acrylate/acrylic acid, such as those available from E. I. du Pont de Nemours and Company of Wilmington, Del. (“DuPont”) under the trademark Nucrel®.

The ECP-2 also may optionally further comprise other suitable additional comonomers, as described above with respect to the ECP-1. Preferably, however, the ECP-2 does not incorporate the other additional comonomers in any significant amount. In one embodiment, the ECP-2 comprises about 3-15 wt %, or about 3-10 wt %, or about 4-7 wt % of copolymerized units of the third olefin of the formula CH₂═C(R⁴)-D. It may optionally further comprise up to about 40 wt %, or about 5-40 wt %, or about 10-40 wt %, or about 20-40 wt %, or about 20-35 wt % of copolymerized units of the first olefin of the formula CH₂═C(R¹)CO₂R². The remainder of the ECP-2 comprises copolymerized units of ethylene and up to about 5 wt % of optional additional comonomers. These weight percentages are based on the total weight of ECP-2. The ECP-2 may have a melt flow rate of about 5-300 g/10 min or about 5-100 g/10 min, as determined in accordance with ASTM D1238 at 190° C. and under a weight of 2.16 kg. Polymers suitable for use as ECP-2 also may be obtained commercially. For example, the ECP-2 used herein may be a copolymer of ethylene/n-butyl acrylate/glycidyl methacrylate, such as those available from DuPont under the trademark Elvaloy®.

Within the cross-linkable blend composition, the ratio of the ECP-1 and the ECP-2 may range from about 90:10 to about 10:90, or about 80:20 to about 20:80, or about 70:30 to about 30:70, or about 60:40 to about 40:60, by weight. In addition, the mole ratio of the carboxylic acid groups comprised in the ECP-1 to the epoxy groups comprised in the ECP-2 is preferably about 10:1 to about 1:10, about 5:1 to about 1:5, about 3:1 to about 1:3, or about 2:1 to about 1:2.

In addition to the ECP-1 and the ECP-2, the cross-linkable blend composition may further include one or more suitable additive(s) that are known in the art. Such additives include, but are not limited to, processing aids, catalysts, flow enhancing additives, lubricants, pigments, dyes, optical brighteners, flame retardants, impact modifiers, nucleating agents, anti-blocking agents (e.g., silica), thermal stabilizers, hindered amine light stabilizers (HALS), UV absorbers, UV stabilizers, dispersants, surfactants, chelating agents, coupling agents, adhesives, primers, reinforcement additives (e.g., calcium carbonate), and combinations of two or more thereof. Suitable additives may be present in the cross-linkable blend composition at a level of about 0.01-15 wt %, or about 0.01-10 wt %, or about 0.01-5 wt %, or about 0.01-1 wt %, in total, based on the total weight of the cross-linkable blend composition.

As is set forth in detail in U.S. Patent Publication No. US2011/0023943, the cross-linkable blend composition of the ECP-1 and the ECP-2 can be prepared by any suitable process, such as melt blending or dry blending. Preferably, during the melt blending processes, the process temperature is maintained at or below about 135° C., or at or below about 130° C., or at or below about 125° C., or at or below about 120° C., to prevent premature cross-linking.

The platelike solar cell module (11) used herein comprises a solar cell element that is formed of one or a plurality of electrically interconnected solar cells. The solar cells used herein may be any article or material that can convert light into electrical energy. Solar cells useful herein include, without limitation, wafer-based solar cells (e.g., monocrystalline silicon (c-Si) or multi-crystalline silicon (mc-Si) based solar cells) and thin film solar cells (e.g., amorphous silicon (a-Si), microcrystalline silicon (μc-Si), cadmium telluride (CdTe), copper indium selenide (CIS), copper-indium-gallium selenide (CIGS), light absorbing dyes, or organic semiconductor based solar cells). Within the solar cell element, the solar cells are electrically interconnected or arranged in a flat plane. In addition, the solar cell element may further comprise electric wirings, such as cross ribbons and bus bars.

The solar cell elements may be bifacial. In such embodiments, all the laminating materials positioned on either side of the solar cell elements should be sufficiently transparent to allow adequate sunlight or reflected sunlight to reach the solar cells. Alternatively, the solar cell elements may have a front sun-facing side (which is also referred to as a front side and, when in actual use conditions, generally faces toward the sun) and a back non-sun-facing side (which is also referred to as a back side and, when in actual use conditions, generally faces away from the sun). The solar cells define the boundary between the front and back sides of the solar cell elements. In such embodiments, all the materials that are present in the laminate layers positioned to the front sun-facing side of the solar cell elements should have sufficient transparency to allow adequate sunlight to reach the solar cells. While the materials present in the laminate layers positioned to the back non-sun-facing side of the solar cell elements need not be transparent.

In addition to the solar cell element, a solar cell module may further comprise encapsulant layer(s) laminated to one or both sides of the solar cell element. The encapsulant layers may be formed of any suitable polymeric materials, such as acid copolymers, ionomers, ethylene/vinyl acetate copolymers (EVA), poly(vinyl acetals) (e.g., poly(vinyl butyral) (PVB)), polyurethanes, poly(vinyl chlorides), polyethylenes (e.g., linear low density polyethylenes), polyolefin block copolymer elastomers, copolymers of α-olefins and α,β-ethylenically unsaturated carboxylic acid esters (e.g., ethylene methyl acrylate copolymers and ethylene butyl acrylate copolymers), silicone elastomers, epoxy resins, and combinations of two or more thereof. Moreover, the encapsulant layers may also be formed of the cross-linkable blend composition disclosed herein.

Further, the solar cell module may further comprise a frontsheet or a backsheet serving as the outermost layer or layers of the module at the sun-facing side and the non-sun-facing side of the solar cell module, respectively. The frontsheet and the backsheet may comprise any suitable sheet or film. Suitable sheets include, for example, glass or plastic sheets, such as polycarbonates, acrylics, polyacrylates, cyclic polyolefins (e.g., ethylene norbornene polymers), polystyrenes (preferably polystyrenes prepared in the presence of metallocene catalysts), polyamides, polyesters, fluoropolymers, or combinations of two or more thereof. In addition, metal sheets, such as aluminum, steel, galvanized steel, or ceramic plates may be used in the backsheet.

Suitable films useful as the frontsheet or the backsheet may be formed of any suitable polymeric materials, such as polyesters (e.g., poly(ethylene terephthalate) (PET) and poly(ethylene naphthalate) (PEN)), polycarbonate, polyolefins (e.g., polypropylene, polyethylene, and cyclic polyolefins), norbornene polymers, polystyrene (e.g., syndiotactic polystyrene), styrene-acrylate copolymers, acrylonitrile-styrene copolymers, polysulfones (e.g., polyethersulfone, polysulfone, etc.), polyamides, poly(urethanes), acrylics, cellulose acetates (e.g., cellulose acetate, cellulose triacetates, etc.), cellophane, silicones, poly(vinyl chlorides) (e.g., poly(vinylidene chloride)), fluoropolymers (e.g., polyvinyl fluoride, polyvinylidene fluoride, polytetrafluoroethylene, and ethylene-tetrafluoroethylene copolymers), and combinations of two or more thereof.

Specific examples of films that may be used in the solar cell module outer layers (e.g., the frontsheet or the backsheet) include, but are not limited to, polyester films (e.g., poly(ethylene terephthalate) films), fluoropolymer films (e.g., Tedlar®, Tefzel®, and Teflon® films available from DuPont). Metal films, such as aluminum foil, may also be used as the backsheets. Further the films used as the backsheets in solar cell modules may be in the form of multi-layer films, such as a fluoropolymer/polyester/fluoropolymer multilayer film (e.g., Tedlar®/PET/Tedlar® or TPT laminate backsheet available from Isovolta AG (Austria), or Madico (U.S.A.), or Krempel Group (Germany).

The frame body (13) included herein has a groove portion (13a) into which the outer periphery of the solar cell module (11) is fitted. The frame body (13) may be formed of any suitable material(s). For example, the frame body (13) used herein may be formed of any suitable metal(s), such as aluminum. With the desire to reduce the overall weight of the module (10), plastic materials have also been used in forming the frame bodies (13). Examples of plastic materials suitable for use herein include, without limitation, polyesters (e.g., poly(ethylene terephthalate) (PET), polybutylene terephthalate (PBT), or poly(trimethylene terephthalate) (PTT)), polyamides (PA), polycarbonates (PC), polyphenyloxides (PPO), and blends thereof. Examples of polymer blends suitable for use in forming the frame bodies (13) include, without limitation, blends of polycarbonate and acrylonitrile butadiene styrene (PC/ABS blends), blends of polycarbonate and poly(ethylene terephthalate) (PC/PET blends), blends of polycarbonate and polybutylene terephthalate (PC/PBT blends), blends of polyamide and acrylonitrile butadiene styrene blends (PA/ABS blends). Moreover, various suitable fillers may also be contained in the plastic materials used herein. Examples of fillers suitable for use herein include, without limitation, talc, glass fibers, carbon fibers, ceramic fibers, calcium carbonates, micas, and combinations thereof.

The framed solar cell module (10) disclosed herein may be prepared by any suitable process. In general, the process may include, (i) preparing a frameless solar cell module (11); and (ii) framing the solar cell module (11) by attaching the outer periphery of the solar cell module (11) into the inside of the groove portion (13a) of a frame body (13), with the sealant material (12) filling up the space between the outer periphery of the solar cell module (11) and the frame body (13). The sealant material is the cross-linkable blend composition disclosed above.

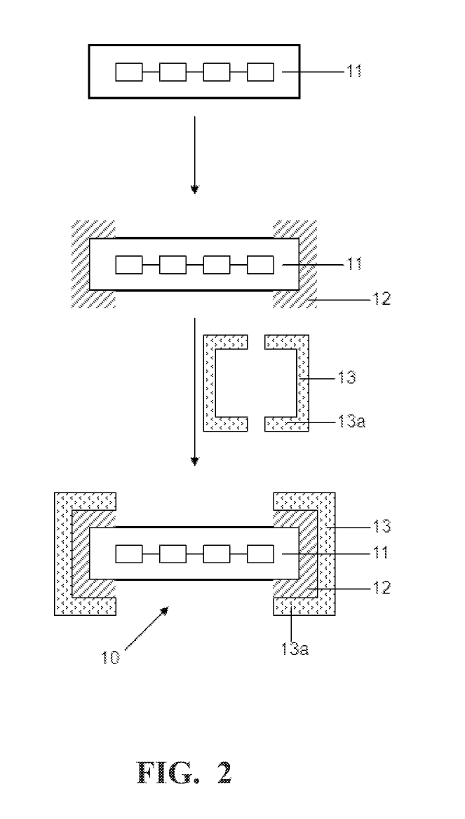

In one embodiment (FIG. 2), the framing step (ii) includes: (a) attaching a polymer strip formed of the cross-linkable blend composition around the outer periphery of the solar cell module (11); and (b) attaching the outer periphery of the solar cell module (11), which is covered by the polymer strip, into the inside of the groove portion (13a) of the frame body (13).

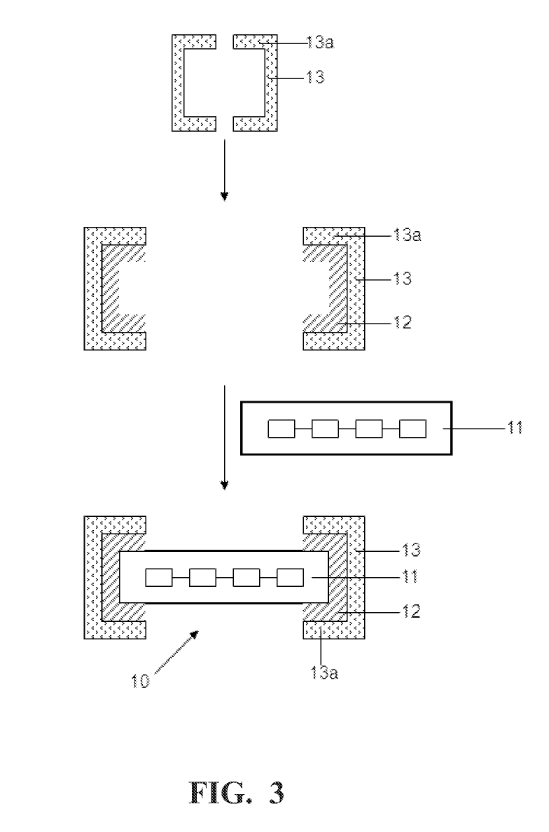

In a further embodiment (FIG. 3), the framing step (ii) includes: (a) attaching a polymer strip formed of the cross-linkable blend composition over the inside of the groove portion (13a) of the frame body (13); and (b) attaching the outer periphery of the solar cell module (11) into the inside of the groove portion (13a) of the frame body (13), which is covered by the polymer strip.

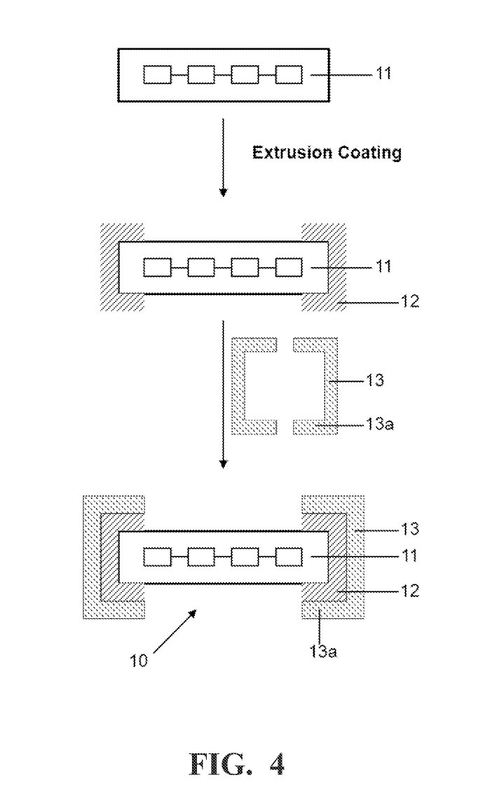

In a yet further embodiment (FIG. 4), the framing step (ii) includes: (a) extrusion coating the cross-linkable blend composition around the outer periphery of the solar cell module (11); and (b) attaching the outer periphery of the solar cell module (11), which is extrusion coated with the cross-linkable blend composition, into the inside of the groove portion (13a) of the frame body (13).

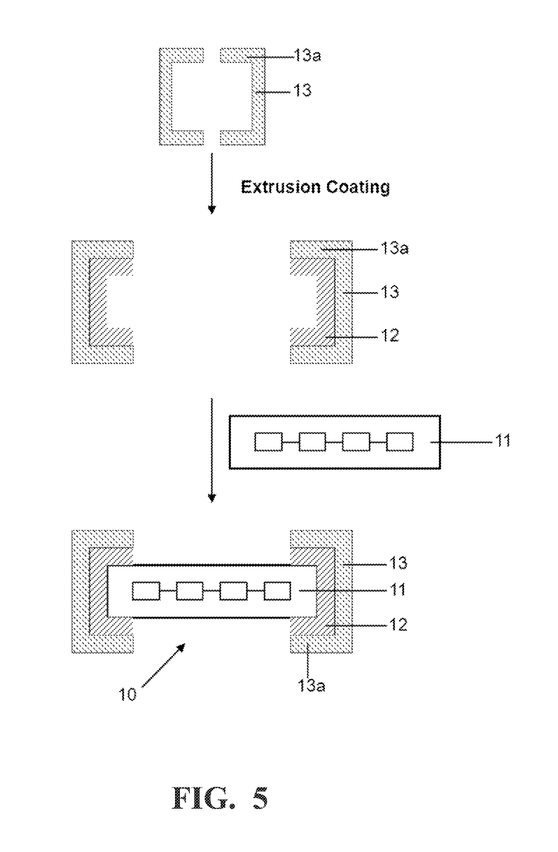

In a yet further embodiment (FIG. 5), the framing step (ii) includes: (a) extrusion coating the cross-linkable blend composition over the inside of the groove portion (13a) of the frame body (13); and (b) attaching the outer periphery of the solar cell module (11) into the inside of the groove portion (13a) of the frame body (13), which is extrusion coated with the cross-linkable blend composition.

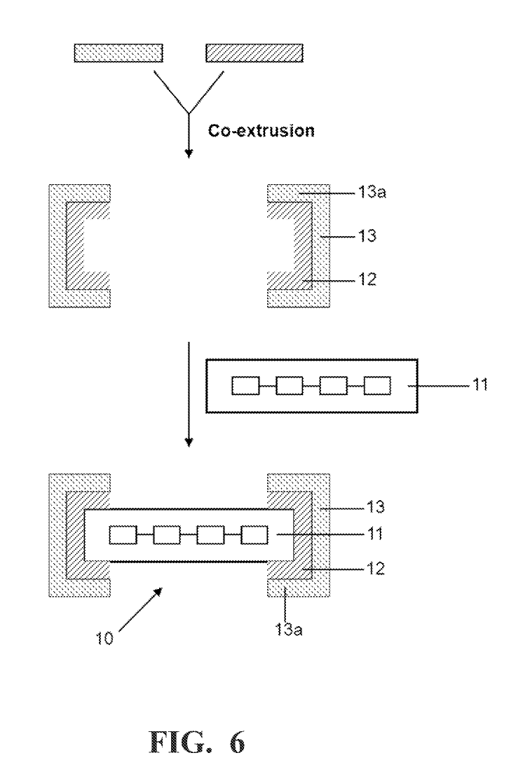

In a yet further embodiment (FIG. 6), the frame body (13) is formed of a plastic material and the framing step (ii) includes: (a) co-extruding a frame body (13), in which the inside layer of the groove portion (13a) of the frame body is formed of the cross-linkable blend composition; and (b) attaching the outer periphery of the solar cell module (11) into the inside of the groove portion (13a) of the frame body (13).

The process may further comprise a curing step (iii), in which the structure that is obtained in the framing step (ii) is cured at a temperature of about 135° C. or higher, or of about 140° C.-180° C. for about 5-60 minutes, or about 5-30 minutes, or about 5-20 minutes. During the curing step (iii), the cross-linkable blend composition is melted and cross-linked. It fills up the space between the frame body (13) and the outer periphery of the solar cell modules (11). By such processes, the sealant material that is comprised in the framed solar cell module (10) disclosed herein is formed of a cross-linked blend composition of the ECP-1 and the ECP-2. Stated alternatively, within the cross-linked blend composition, at least a portion of the carboxylic acid groups comprised in the ECP-1 are reacted with at least a portion of the epoxy groups comprised in the ECP-2 to form cross-links between the ECP-1 and the ECP-2. Also, as is set forth in detail in U.S. Patent Publication No. US2011/0023943, the cross-links between ECP-1 and the ECP-2 are formed during this high-temperature step, and the rate at which the reaction proceeds depends on one or more of the curing temperature, the melt flow rate of the blend, the concentration of catalyst, if any, and the concentration of the reactive monomers that are present.

Using the cross-linkable blend compositions described herein as the sealant material has a number of advantages over silicone glues. Among them, the cross-linkable blend composition may be made into strips with various profiles by standard thermoplastic extrusion process. Such strips can then be readily applied between the outer periphery of the solar cell module (11) and the groove portion (13a) of the frame body (13) and therefore the framing process may be very much simplified. Further, the time that is required for curing the cross-linkable blend composition (about 30 minutes or so) is much shorter than the time that is required for curing silicone glues (at least about 6 hours). Yet further, when silicone glue is used as the sealant material, excess residues often contaminate the module surfaces after the framing process and an extra cleaning step is therefore necessary after the framing process. However, when the cross-linkable blend composition described herein is used as the sealant material, no residues or very little excess residues contaminate the module surfaces after the framing process and therefore no extra cleaning step is needed.

The following examples are provided to describe the invention in further detail. These examples, which set forth a preferred mode presently contemplated for carrying out the invention, are intended to illustrate and not to limit the invention.

### EXAMPLES

### Materials

Cross-linkable Blend Sheet-1 (CBS-1): a 0.5 mm thick polymer sheet that was prepared as follows. First, a dry blend of ECP-1 and ECP-2 (60:40 by weight) was prepared in a cement mixer. Then, the dry blend was introduced into a cast film machine (manufactured by Davis Standard) to produce the polymer sheet, wherein the extrusion temperature was set at 120° C. and the line speed at 2 m/min. The ECP-1 used herein was an ethylene/n-butyl acrylate/acrylic acid copolymer that had a melt flow rate of 60 g/10 min and comprised copolymerized units of ethylene (65.8 wt %), n-butyl acrylate (28 wt %), and acrylic acid (6.2 wt %). The ECP-2 used herein was an ethylene/n-butyl acrylate/glycidyl methacrylate copolymer that had a melt flow rate of 12 g/10 min and comprised copolymerized units of ethylene (66.75 wt %), n-butyl acrylate (28 wt %), and glycidyl methacrylate (5.25 wt %);
Cross-linkable Blend Sheet-2 (CBS-2): a 0.5 mm thick polymer sheet that was prepared similarly as CBS-1 with the exception that a 0.25 wt % of silane (Dow Corning™ Z6040 silane obtained from Dow Corning (U.S.A.)) was added into the dry blend;
Silicone Glue: TONSAN 1527 silicone sealant (for use in solar cell panels) that was obtained from Beijing Tonsan Adhesive Inc. (China).
Glass Sheet: 170×150×2 mm glass sheets obtained from Suzhou Qinghua Guangxue Jingpian Co., Ltd. (China):
EVA Sheet: 0.45 mm thick Revax™ ethylene vinyl acetate (EVA) sheet obtained from Wenzhou Ruiyang Photovoltaic Material Co. Ltd. (China);
Solar Cell: monocrystalline silicon solar cells obtained from JA Solar Holdings Co., Ltd. (China), with a Product ID of 125SOR22B;
TPT Sheet: 0.32 mm thick laminated backsheets obtained from Krempel Group under the trade name AKASOL™ PTL3;
Aluminum Frame Bars: pre-formed aluminum framing materials having a length of 172 mm or 152 mm, which were obtained from Jiangyin GuangYue Solar Science&Technology Co., Ltd., (China).

### Comparative Example CE1 and Examples E1-E2

First, solar cell modules with the structure of “Glass/EVA Sheet/Solar Cell/EVA Sheet/TPT Sheet” were prepared by processing the assembly in a vacuum laminator (Model Meier Icolam 10/08 manufactured by Meier Vakuum Technik GMBH) for 5 min at 125° C. Each of the solar cell modules thus prepared had a dimension of 172×152 mm.

In E1 and E2, a 1.5 cm wide sealant strip made from CBS-1 or CBS-2, respectively, was placed around the outer periphery of the solar cell module. Thereafter, two 172 mm long aluminum frame bars and two 152 mm long aluminum frame bars were locked around the outer periphery of the solar cell module, which was covered by the sealant strip. The whole assembly was then heated in a 150° C. oven for 15 min to form the final framed solar cell module. The framed solar cell modules were then subjected to aging in a damp heat oven (85° C. and 85% RH) for time periods of varying length. The power generation values of the framed solar cell modules (before and after aging) were measured in accordance with the method described in IEC61215, at room temperature and 50% RH using a Spi-Sun Simulator™ 3500 simulator (manufactured by Spire Solar (U.S.A.)). Results are tabulated in Table 1.

In CE1, the solar cell module was further treated in a 150° C. oven for 15 min, and then cooled down to room temperature. Thereafter, silicone glue was applied over the inside of the groove portion of the four aluminum frame bars (two 172 mm long aluminum frame bars and the two 152 mm long aluminum frame bars). Then, the four aluminum frame bars were locked around and bonded to the outer periphery of the solar cell module. After curing at room temperature for about 24 hours, the excess silicone glue that was left over the front side of the module was wiped away. The power generation value of the framed solar cell module thus prepared (before and after aging) was measured and the results are tabulated in Table 1.

As is demonstrated by the results, when the cross-linked blend composition disclosed herein was used as the sealant material in framed solar cell modules, the power generation value was comparable to or higher than (after 42-day or 97-day aging) that of those framed solar cell modules in which silicone glue was used as the sealant material. In addition, the process in E1 and E2 were simplified and less time consuming than the process in CE1.

TABLE 1

| | Power (Watt) | | | | | | |
|---|---|---|---|---|---|---|---|
| Sam- | | 7 | 14 | 27 | 38 | 42 | 97 |
| ple | 0 | days* | days* | days* | days* | days* | days* |
| CE1 | 2.4471 | 2.4099 | 2.4173 | 2.4456 | 2.4193 | 2.4053 | 2.3311 |
| E1 | 2.4475 | 2.4234 | 2.4341 | 2.4427 | 2.4087 | 2.4137 | 2.353 |
| E2 | 2.4614 | 2.432 | 2.4446 | 2.4584 | 2.4304 | 2.4182 | 2.3427 |

Note:
*Aging time.

While certain of the preferred embodiments of the present invention have been described and specifically exemplified above, it is not intended that the invention be limited to such embodiments. Rather, it is to be understood that even though numerous characteristics and advantages of the present invention have been set forth in the foregoing description, together with details of the structure and function of the invention, the disclosure is illustrative only, and changes may be made in detail, especially in matters of shape, size and arrangement of parts within the principles of the invention to the full extent indicated by the broad general meaning of the terms in which the appended claims are expressed.

What is claimed is:

1. A framed solar cell module comprising:
(a) a platelike solar cell module comprising a solar cell element formed of one or a plurality of electrically interconnected solar cells;
(b) a frame body having a groove portion, into which the outer periphery of the solar cell module is fitted; and
(c) a sealant material so provided as to fill up a space between the outer periphery of the solar cell module and the groove portion of the frame body, the sealant material being formed of a cross-linkable blend composition comprising 10-90 wt % of an Ethylene Copolymer-1 and 10-90 wt % of an Ethylene Copolymer-2, wherein the total wt % of the components comprised in the cross-linkable blend composition is 100 wt %, and further wherein
(i) the Ethylene Copolymer-1 consists essentially of copolymerized units of ethylene, optionally up to 40 wt % of copolymerized units of a first olefin having a formula of CH₂═C(R¹)CO₂R², and 2-30 wt % of copolymerized units of a second olefin having a formula of CH₂═C(R³)COOH, wherein the total wt % of the copolymerized units comprised in the Ethylene Copolymer-1 is 100 wt %, and further wherein R¹ is hydrogen or an alkyl group, R² is an alkyl group, and R³ is hydrogen or an alkyl group;
(ii) the Ethylene Copolymer-2 consists essentially of copolymerized units of ethylene, optionally up to 40 wt % of copolymerized units of the first olefin, and 3-15 wt % of copolymerized units of a third olefin having a formula of CH₂═C(R⁴)-D, wherein the total wt % of the copolymerized units comprised in the Ethylene Copolymer-2 is 100 wt %, and further wherein R⁴ is hydrogen or an alkyl group; -D is a moiety selected from the group consisting of —CO₂R⁵, —CO₂R⁶—R⁵, —R⁶—R⁵, —O—R⁵, and —R⁵; R⁵ is a moiety containing an epoxy group; and R⁶ is an alkylene group; and
(iii) none of the first, second or third olefin is a dicarboxylic acid or a di-ester, mono-ester or anhydride of the dicarboxylic acid.

2. The framed solar cell module of claim 1, wherein the sealant material comprises a product of cross-linking the cross-linkable blend composition, and wherein in said product at least a portion of the carboxylic acid groups comprised in the Ethylene Copolymer-1 are reacted with at least a portion of the epoxy groups comprised in the Ethylene Copolymer-2 to form cross-links between the Ethylene Copolymer-1 and the Ethylene Copolymer-2.

3. The framed solar cell module of claim 1, wherein the weight ratio of the Ethylene Copolymer-1 and the Ethylene Copolymer-2 comprised in the cross-linkable blend composition ranges from 80:20 to 20:80, or from 70:30 to 30:70; or from 60:40 to 40:60.

4. The framed solar cell module of claim 1, wherein the first olefin is selected from the group consisting of methyl acrylate, methyl methacrylate, ethyl acrylate, ethyl methacrylate, butyl acrylate, and butyl methacrylate; or wherein the second olefin is an acrylic acid or a methacrylic acid; or wherein the moiety R⁵ is a glycidyl group, a 1,2-cyclohexenyl oxide group, or a 1,2-epoxy group.

5. The framed solar cell module of claim 1, wherein the Ethylene Copolymer-1 comprises 5-40 wt %, or 10-35 wt %, or 10-30 wt % of copolymerized units of the first olefin; or wherein the Ethylene Copolymer-1 comprises 5-20 wt % or 5-15 wt % of copolymerized units of the second olefin; or wherein the Ethylene Copolymer-1 has a melt flow rate of 5 g/10 min or higher, or 30 g/10 min or higher, or 30-500 g/10 min, as determined in accordance with ASTM D1238 at 190° C. and under a weight of 2.16 kg.

6. The framed solar cell module of claim 5, wherein the Ethylene Copolymer-1 is a copolymer of ethylene/n-butyl acrylate/acrylic acid.

7. The framed solar cell module of claim 1, wherein the Ethylene Copolymer-2 comprises 3-10 wt % or 4-7 wt % of copolymerized units of the third olefin; or wherein the Ethylene Copolymer-2 comprise 5-40 wt %, or 10-40 wt %, or 20-40 wt %, or 20-35 wt % of copolymerized units of the first olefin; or wherein the Ethylene Copolymer-2 has a melt flow rate of 5-300 g/10 min or 5-100 g/10 min, as determined in accordance with ASTM D1238 at 190° C. and under a weight of 2.16 kg.

8. The framed solar cell module of claim 7, wherein the Ethylene Copolymer-2 is a copolymer of ethylene/n-butyl acrylate/glycidyl methacrylate.

9. The framed solar cell module of claim 1, wherein the frame body is formed of a metallic material or a plastic material.

10. A method for preparing the framed solar cell module of claim 1, comprising the steps of:
(a) providing a platelike solar cell module comprising a solar cell element formed of one or a plurality of electrically interconnected solar cells;
(b) providing a frame body having a groove portion;
(c) providing a sealant material formed of the cross-linkable blend composition; and
(d) attaching the outer periphery of the solar cell module into the inside of the groove portion of the frame body, with the sealant material filling up the space between the outer periphery of the solar cell module and the frame body, to obtain the framed solar cell module.

11. The method of claim 10, wherein step (d) comprises: (i) attaching a polymer strip formed of the sealant material around the outer periphery of the solar cell module; and (ii) attaching the outer periphery of the solar cell module, which is covered by the polymer strip, into the inside of the groove portion of the frame body.

12. The method claim 10, wherein step (d) comprises: (i) attaching a polymer strip formed of the sealant material over the inside of the groove portion of the frame body; and (ii) attaching the outer periphery of the solar cell module into the inside of the groove portion of the frame body, which is covered by the polymer strip.

13. The method of claim 10, wherein step (d) comprises: (i) extrusion coating the sealant material around the outer periphery of the solar cell module; and (ii) attaching the outer periphery of the solar cell module, which is extrusion coated with the sealant material, into the inside of the groove portion of the frame body.

14. The method of claim 10, wherein step (d) comprises: (i) extrusion coating the sealant material over the inside of the groove portion of the frame body; and (ii) attaching the outer periphery of the solar cell module into the inside of the groove portion of the frame body, which is extrusion coated with the sealant material.

15. The method of claim 10, further comprising the step of (e) subjecting the framed solar cell module obtained in step (d) to curing at a temperature of 135° C. or higher, or 140° C.-180° C., and wherein the curing duration is 5-60 minutes, or 5-30 minutes, or 5-20 minutes.

16. A method for preparing the framed solar cell module of claim 1, comprising the steps of:
(a) providing a platelike solar cell module comprising a solar cell element formed of one or a plurality of electrically interconnected solar cells;
(b) co-extruding a polymer composition and the cross-linkable blend composition to form a frame body, wherein the frame body has a groove portion and the inside layer of the groove portion is formed of the cross-linkable blend composition; and
(c) attaching the outer periphery of the solar cell module into the inside of the groove portion of the frame body.

17. The method of claim 16, further comprising the step of (d) subjecting the framed solar cell module obtained in step (c) to curing at a temperature of 135° C. or higher, or 140° C.-180° C., and wherein the curing duration is 5-60 minutes, or 5-30 minutes, or 5-20 minutes.
